(19) United States
(12) Patent Application Publication
(10) Pub. No.: US 2015/0159272 A1
(43) Pub. Date: Jun. 11, 2015

(54) SUBSTRATE HEATING DEVICE AND PROCESS CHAMBER

(71) Applicant: INOCT CO., LTD, Hwaseong-Si, Gyeonggi-Do (KR)

(72) Inventors: Song Keun Yoon, Yongin-Si (KR); Jong Hwa Lee, Suwon-Si (KR); Hyeog Joon Ko, Suwon-Si (KR); Jang Hyeok Lee, Suwon-Si (KR)

(21) Appl. No.: 14/411,481

(22) PCT Filed: Apr. 3, 2013
(86) PCT No.: PCT/KR2013/002749

§ 371 Date: Dec. 26, 2014

(30) Foreign Application Priority Data
Jun. 27, 2012 (KR) 10-2012-0069226

(51) Int. Cl. C23C 16/455; C23C 16/46; H01L 21/67

(52) U.S. Cl. CPC C23C 16/45544; H01L 21/67098; C23C 16/46

(57) ABSTRACT

The present invention relates to a process chamber which includes a substrate heating device. The substrate heating device of the process chamber according to one embodiment of the present invention has a boat in which a plurality of substrates are stacked apart from each other, and a chamber housing in which the boat is positioned in an inner space for process gas to flow between the substrates which are stacked apart from each other on the inner side wall, and the present invention includes a first heating body which generates heat in the lower portion of the boat to heat the substrate. Moreover, the boat comprises an upper plate, a lower plate, a plurality of support bars connecting the upper plate with the lower plate, and a plurality of substrate seat grooves formed on the side walls of the support bars.

### TECHNICAL FIELD

The present invention relates to a process chamber including a substrate heating device, and more particularly, to a substrate heating device for heating a substrate when a process is performed and a process chamber to which the substrate heating device is applied.

### BACKGROUND ART

As semiconductor devices gradually decrease in scale, demand for ultra-thin films increases. In addition, as a contact hole is reduced in size, limitations in step coverage are increasing more and more.

In general, when semiconductor devices are manufactured in a semiconductor apparatus, a sputtering, chemical vapor deposition (CVD), or atomic layer deposition (ALD) method may be used for uniformly depositing a thin film. In case of the CVD or ALD, a process gas may be injected in a showerhead or nozzle manner.

FIG. 1 is a schematic view of a showerhead-type atomic layer deposition device.

The showerhead-type atomic layer deposition device includes a process chamber 2 having a reaction space in which a reaction gas and purge gas are successively supplied to deposit an atomic layer on a substrate 3, a substrate support 4 disposed in a lower portion of the process chamber 2 to seat the substrate 3 thereon, a showerhead 5 disposed to face the substrate support 4 to inject a gas into a reaction space 1, and a valve 6 disposed in a supply path that extends to the showerhead 5 to open or close the gas supply. Here, the process chamber 2 is connected to a pumping unit for discharging the gas supplied into the reaction space 1 to the outside. As described above, the atomic layer deposition according to the related art includes the process chamber 2 having a relatively small volume to quickly supply and remove the gas in the reaction space 1 so as to expose the substrate to the reaction gas and purge gas at a uniform density.

In the case of the CVD or ALD device, substrate processing and production capabilities may not be superior. This is done for a reason in which it is difficult to process a large number of substrates at the same time because the number of substrates mounted on the substrate support is limited even though the CVD or ALD process is performed in a state where a plurality of substrates are placed on the substrate support. Thus, a process chamber that is capable of processing a large amount of substrates is required. In this case, to improve substrate processing capacity, it is necessary to effectively provide a unit for supplying heat energy to the substrate.

(PRIOR PATENT DOCUMENT) Korean Patent Publication No. 10-2005-0080433

### DISCLOSURE OF THE INVENTION

### Technical Problem

The technical subject of the present invention is to provide a substrate heating device for improving substrate processing capacity in a process chamber in which a substrate processing process such as chemical vapor deposition (CVD) or atomic layer deposition (ALD) is performed. Also, the technical subject of the present invention is to improve uniformity in thin film that is deposited on a substrate. Also, the technical subject of the present invention is to provide a process chamber including a substrate heating device.

### Technical Solution

A substrate heating device according to an embodiment of the present invention including a boat in which a plurality of substrates are stacked to be spaced apart from each other and a chamber housing in which the boat is disposed in an inner space thereof to inject a process gas between substrates that are stacked to be spaced apart from each other in the boat through an injection hole defined in an inner sidewall thereof, the substrate heating device includes a first heater configured to generate heat in a lower portion of the boat to heat the substrates. Also, the boat may include an upper plate, a lower plate, a plurality of support bars connecting the upper plate to the lower plate, and a plurality of substrate seat grooves defined in sidewalls of the support bars.

Also, the first heater may be disposed on a top surface of the lower plate or a bottom surface of the upper plate, or the first heater may be buried in the lower plate or the upper plate.

Also, a boat elevation unit may include a boat support configured to support the lower plate and an elevation rotation driving shaft passing through a bottom surface of the lower chamber housing to elevate the boat support.

Also, the first heater may include a support shaft connecting the lower plate to the boat support in a state where the lower plate and the boat support are spaced apart from each other and a heating plate fixed to the support shaft, the heating plate being horizontally disposed in a space defined between the lower plate and the boat support.

Also, a process chamber includes a boat in which a plurality of substrates are stacked to be spaced apart from each other, a chamber housing configured to lift the boat, thereby allowing the boat to be disposed in an inner space thereof, the chamber housing being configured to horizontally inject a process gas from a sidewall thereof, thereby allowing the process gas to flow between the substrates stacked to be apart from each other and discharge the process gas to the outside, a boat elevation unit configured to elevate the boat into the chamber housing, a substrate transfer gate passing through one sidewall of the chamber housing, and a heating unit disposed in the boat within the inner space of the chamber housing to heat the substrates that are stacked to be spaced apart from each other.

Also, the chamber housing may include a lower chamber housing having a first inner space that is an inner space thereof, an upper chamber housing disposed above the lower chamber housing and having a second inner space that is an inner space thereof, the upper chamber housing being configured to horizontally inject the process gas from one side inner wall thereof, thereby allowing the process gas to flow between the substrates stacked to be spaced apart from each other and discharge the process gas to the outside.

### Advantageous Effects

According to the embodiments of the present invention, when the substrate processing processes such as the CVD and ALD are performed, the substrate may be effectively heated in the process chamber in which the process gas is injected from the sidewall thereof. Also, when the substrate is heated and processed, the uniform heat distribution may be realized in the whole space within the process chamber. Thus, the thin film that is processed in the process chamber may have uniform film quality. Also, a space that is occupied by the substrate heating device may be minimized in volume in the process chamber for injecting the process gas.

### BRIEF DESCRIPTION OF THE DRAWINGS

FIG. 1 is a schematic view of a showerhead-type atomic layer deposition device.

FIG. 2 is a perspective view illustrating an exterior of a process chamber according to an embodiment of the present invention.

FIG. 3 is an exploded view of the process chamber according to an embodiment of the present invention.

FIG. 4 is a cross-sectional view of the process chamber in which a boat ascends or descends according to an embodiment of the present invention.

FIG. 5 is a view illustrating a state in which the boat ascends for each stage as a substrate is mounted on the boat according to an embodiment of the present invention.

FIG. 6 is a view illustrating a state in which a process gas inflow body and a process gas discharge space body are provided in an inner sidewall of an upper inner housing according to an embodiment of the present invention.

FIG. 7 is a view illustrating a flow of a process gas in an upper side of the process chamber according to an embodiment of the present invention.

FIG. 8 is a view illustrating a state in which a lower inner housing and the boat are coupled and sealed to each other according to an embodiment of the present invention.

FIG. 9 is a view illustrating a process in which the substrate is loaded on the boat and is thermally processed within a chamber housing, and then, is unloaded again from the boat according to an embodiment of the present invention.

FIG. 10 is a view illustrating a state in which a heat line that is a second heater is provided in an inner wall of an upper chamber inner housing according to an embodiment of the present invention.

FIG. 11 is a view illustrating a state in which a heat line that is a second heater is buried in a lower or upper plate according to an embodiment of the present invention.

FIG. 12 is a view illustrating a structure in which a heating plate that is a first heater is disposed under the lower plate according to an embodiment of the present invention.

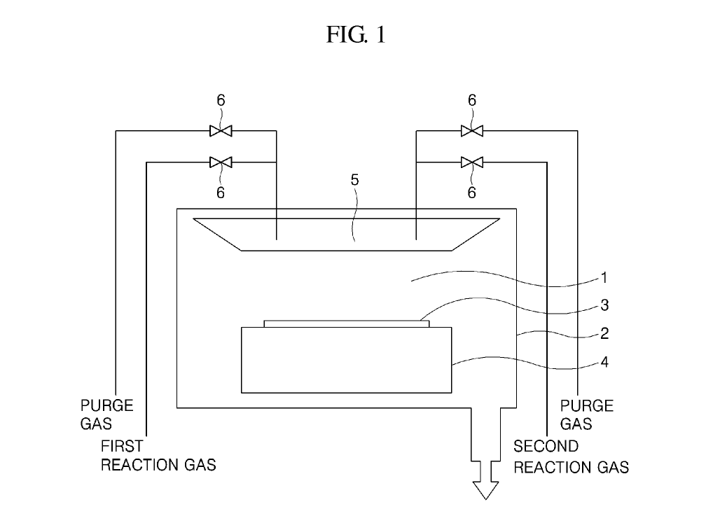

### MODE FOR CARRYING OUT THE INVENTION

Hereinafter, specific embodiments will be described in detail with reference to the accompanying drawings. The present invention may, however, be embodied in different forms and should not be construed as limited to the embodiments set forth herein. Rather, these embodiments are provided so that the present invention will be thorough and complete, and will fully convey the scope of the present invention to those skilled in the art. In the figures, like reference numerals refer to like elements throughout.

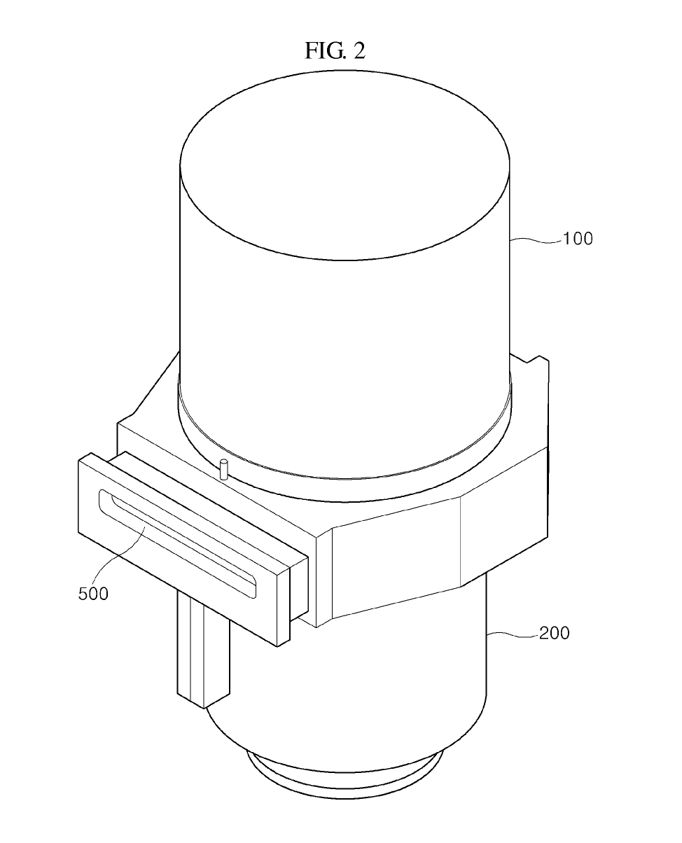

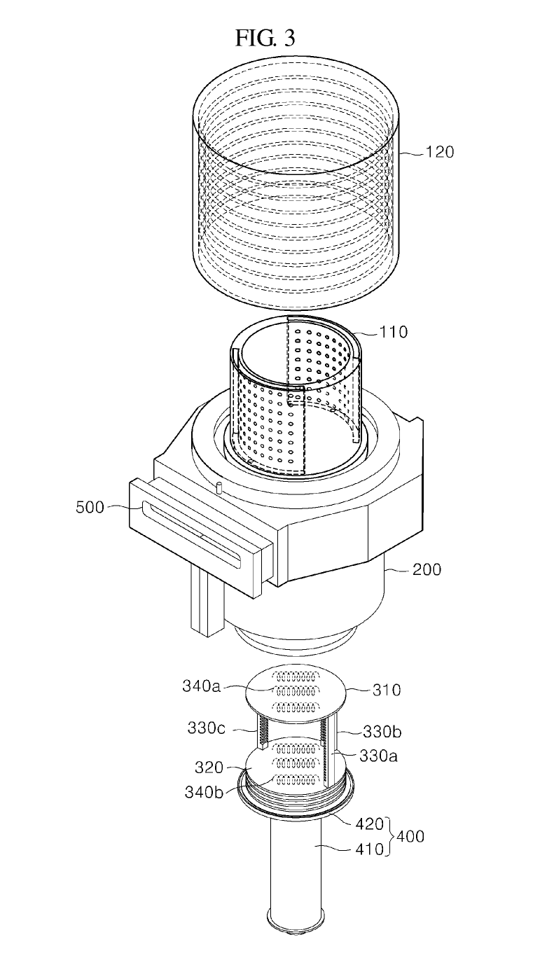

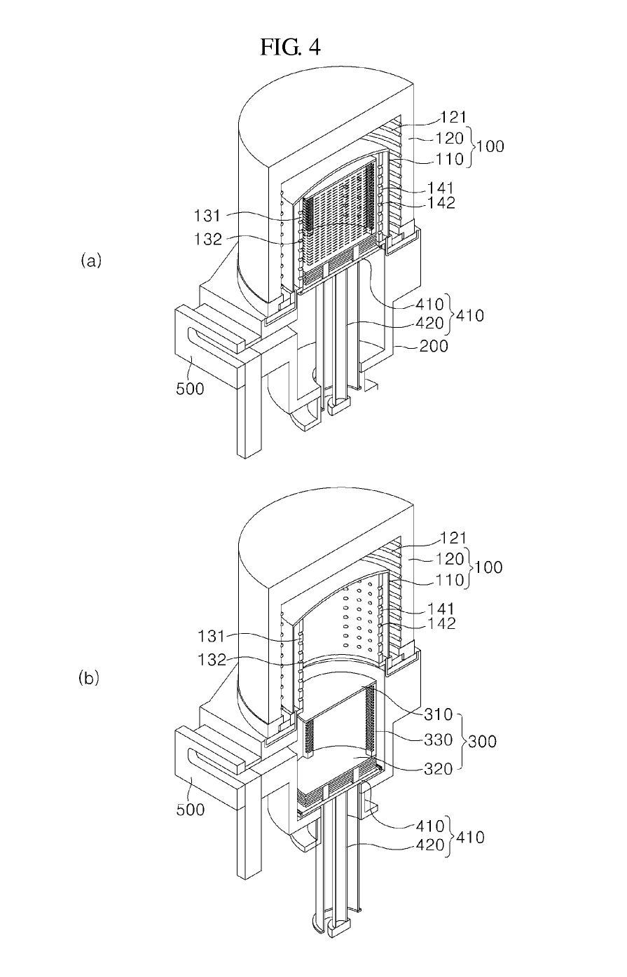

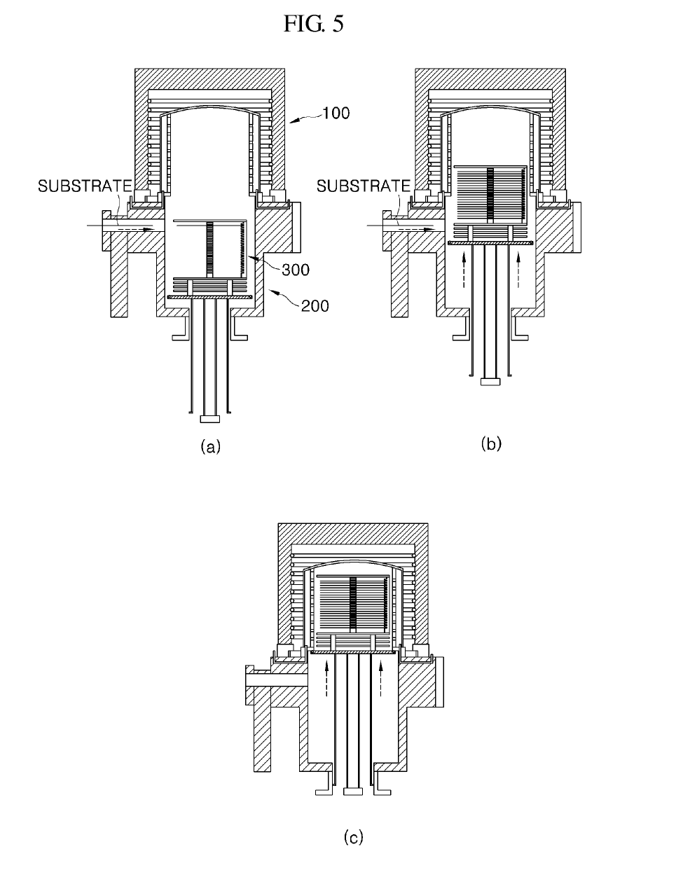

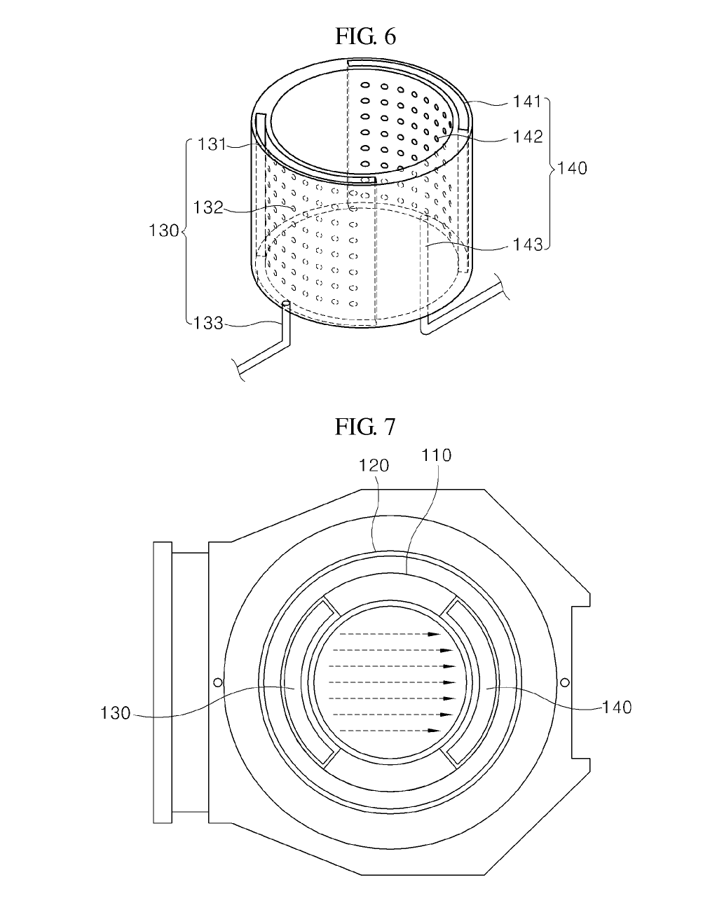

FIG. 2 is a perspective view illustrating an exterior of a process chamber according to an embodiment of the present invention, FIG. 3 is an exploded view of the process chamber according to an embodiment of the present invention, FIG. 4 is a cross-sectional view of the process chamber in which a boat ascends or descends according to an embodiment of the present invention, FIG. 5 is a view illustrating a state in which the boat ascends for each stage as a substrate is mounted on the boat according to an embodiment of the present invention, and FIG. 6 is a view illustrating a state in which a process gas inflow body and a process gas discharge space body are provided in an inner sidewall of an upper inner housing according to an embodiment of the present invention.

A process chamber provides a space in which a plurality of substrates are vertically stacked to be spaced apart from each other to allow a process gas to flow between the plurality of substrates, thereby performing substrate processing processes such as a deposition process, an etching process, and the like on the substrates so as to improve substrate processing capability. For this, the process chamber includes a boat 300 in which a plurality of substrates are stacked to be spaced apart from each other, chamber housings 100 and 200 disposed on a sidewall thereof to horizontally inject a process gas and flow between the spaced and stacked substrates, thereby discharging the process gas to the outside, a boat elevation unit 400 for elevating the boat within the chamber housings 100 and 200, and a substrate transfer gate 500 passing through one sidewall of the chamber housings 100 and 200.

Since the plurality of substrates are vertically stacked to be spaced apart from each other on the boat 300, a gap may be formed between the stacked substrates to allow the process gas to be introduced therethrough and then to flow in an opposite side. Thus, the process gas may contact a top surface of each of the substrates to perform a processing process such as a deposition or etching process on the substrates. To stacking the substrates in the state where the substrates are spaced apart from each other, the boat 300 includes an upper plate 310, a lower plate 320, a plurality of support bars 330 (330a, 330b, and 330c) connecting the upper plate 310 to the lower plate 320, and a plurality of substrate seat grooves 331 defined in sidewalls of the support bars 330. Each of the substrate seat grooves 331 may be a groove that is recessed from the sidewall of each of the support bars 330. Here, the substrate may be seated into the groove. The boat may successively repeatedly expose the substrate to a source gas, a purge gas, and a reaction gas while rotating.

The substrate transfer gate 500 may be a gate that is disposed on one sidewall of the lower chamber housing 200 to allow the substrate to be accessible to the boat 300. When the substrate is loaded on or unloaded from the boat 300, the substrate may be transferred through the substrate transfer gate.

The boat elevation unit 400 may elevate the boat 300 between an inner space of the upper chamber housing 100 and an inner space of the lower chamber housing 200. For this, the boat elevation unit 400 includes a boat support 420 and an elevation rotation driving shaft 410. The boat support 420 has a top surface supporting the lower plate 320. The elevation rotation driving shaft 410 may pass through a bottom surface of the lower chamber housing 200 to support a bottom surface of the boat 300, i.e., the lower plate 320 of the boat 300. The bottom surface of the boat support 420 is connected to the elevation rotation driving shaft 410 to ascend or descend according to the driving of the vertically reciprocating driving source such as a motor. Here, boat 300 may ascend or descend through a vertical piston reciprocating motion of the boat support 420. Also, the elevation rotation driving shaft 410 may not elevate the boat at once when the boat is elevated (ascends/descends), but may allow the boat to ascend or descend for each stage. For example, when the substrate is inserted and seated into the substrate seat groove of the boat through the substrate transfer gate as illustrated in FIG. 5A, the boat elevation unit may further left the boat by one stage to allow the next substrate seat groove to reach the substrate transfer gate as illustrated in FIG. 5B. As described above, the boat may ascend for each stage to seat the substrate into each of the substrate seat grooves. Then, as illustrated in FIG. 5C, the substrate may be mounted into the substrate seat groove and inserted into the inner space of the upper chamber housing. Also, the elevation rotation driving shaft may rotate the boat support to rotate the boat connected to the boat support. Thus, when the processes are performed regardless of a chemical vapor deposition (CVD) process and an atomic layer deposition (ALD) process, the boat may be rotated to allow the substrate mounted on the boat to be successively exposed to the source gas, the purge gas, and the reaction gas.

The chamber housings 100 and 200 may lift the boat to allow the boat to be disposed in the inner space thereof and may horizontally inject the process through one side inner wall thereof to allow the process gas to flow between the spaced and stacked substrates, thereby discharging the process gas to the outside. The chamber housing according to an embodiment of the present invention may be constituted by the lower chamber housing 200 and the upper chamber housing 100.

The lower chamber housing 200 may have an opened upper side and an inner space (hereinafter, referred to as a “first inner space”). As illustrated in FIG. 4B, in a state where the process is completed to allow the substrate to be unloaded, the descending boat 300 may be disposed in the first inner space of the lower chamber housing 200. On the other hand, when the substrate is loaded into the substrate seat groove of the boat by each stage to ascend, the boat 300 may not exist in the first inner space of the upper chamber housing 100.

The upper chamber housing 100 may be disposed on the lower chamber housing 200 in a state where a lower side of the upper chamber housing 100 is opened to define an inner space (hereinafter, referred to as a “second inner space”). The boat ascending from the first inner space of the lower chamber housing is disposed in the second inner space of the upper chamber housing 100. Here, the substrates may be in a state in which the substrates are stacked to be spaced apart from each other and mounted into the substrate seat groove of the boat. The process gas is injected from one side inner wall of the upper chamber housing 100 to flow between the spaced and stacked substrates on the boat. Then, the process gas may pass through the other inner sidewall of the upper chamber housing and be discharged to the outside.

When the process gas is injected from the one side inner wall to the other side inner wall of the upper chamber housing 100, the upper chamber housing 100 may be provided as a single wall. Alternatively, the upper chamber housing 100 may be provided as a double wall. That is, the upper chamber housing 100 may be provided as a housing having a double structure including an upper chamber inner housing 110 and an upper chamber outer housing 120 surrounding the upper chamber inner housing 110. The boat 300 ascending from the lower chamber housing 200 is accommodated into the upper chamber inner housing 110 that is disposed at a relatively inner side of the double structure, and the upper chamber outer housing 120 that is disposed at a relatively outer side of the double structure may surround the top surface and sidewall of the upper chamber inner housing 110 in a state where the upper chamber outer housing 120 is spaced apart from the top surface and sidewall of the upper chamber inner housing 110.

A process gas injection unit for injecting the process gas toward the other side inner wall that is opposite to the one side inner wall of the upper chamber inner housing 110 and a process gas discharge unit for discharging the process gas within the housing to the outside are disposed on the one side inner wall of the upper chamber inner housing 110. As the process gas is injected toward the other side inner wall opposite to the one side inner wall, the process gas may flow onto the boat existing in the inner space of the upper chamber housing.

As illustrated in FIG. 6, the process gas injection unit 130 includes a process gas inflow space body 131 having an inner space, a plurality of gas injection holes 132 defined in a wall of the process gas inflow space body that is adjacent to the boat, and a process gas supply tube 133 for introducing the process gas into the inner space of the process gas inflow space body 131. The process gas inflow space body 131 may be a space body having an inner space defined by upper/lower and left/right walls. The gas introduced from the process gas supply tube 133 may exist in the inner space. A plurality of gas injection holes 132 passing toward the inner space of the process gas inflow space body 131 are defined in a wall of the process gas inflow space body. The process gas may be introduced into the inner space of the upper chamber inner housing through the gas injection holes 132. The gas injection holes 132 may be provided in plurality in positions that respectively match the gaps between the mounted substrates. The wall of the process gas inflow space wall may be a wall facing the boat. The process gas supply tube 133 may introduce the process gas into the inner space of the process gas inflow space body 131. That is, the process gas stored in a process gas storage tank may be supplied into the process gas inflow space body 131 through the process gas supply tube 133. Thus, a tube connected to the process gas storage tank may extend along the wall of the upper chamber inner housing to define the process gas supply tube 133. Thus, the process gas may be supplied into the process gas inflow space body through the process gas supply tube 133.

Also, the upper chamber inner housing includes a process gas discharge unit 140 for discharging the process gas that is used for the substrate processing process to the outside. As illustrated in FIG. 6, the process gas discharge unit 140 includes a process gas discharge space body 141, a gas discharge hole 142, a process gas discharge tube 143, and a discharge pump (not shown). The process gas discharge space body 141 may be a space body having an inner space defined by upper/lower and left/right walls. The process gas remaining within the upper chamber inner housing 110 after being used for the substrate processing may be introduced into the process gas discharge space body 141 to exist in the process gas discharge space body 141. The gas discharge hole 142 may be provided in plurality of in a surface of the process gas discharge space body. The process remaining in the inner space of the upper chamber inner housing after being used for the substrate processing may flow into the process gas discharge space body 141 through the gas discharge hole 142. The wall of the process gas discharge space body 141, in which the gas discharge hole is defined, may be a surface facing the boat. The process gas discharge tube 143 connects the inner space of the process gas discharge space body to the discharge pump. The process gas discharge tube 143 may be connected to the inside of the process gas and then be connected to the discharge pump (not shown) along the inside of the wall of the upper chamber inner housing. Thus, the process gas within the process gas discharge space body 141 may be discharged to the outside through the process gas discharge tube 143. The discharge pump (not shown) may be pumped for discharging the process gas to the outside through the process gas discharge tube.

As described above, the process gas inflow space body 131 and the process gas discharge space body 141 each of which has the inner space are defined in the wall of the upper chamber inner housing. Here, the process gas inflow space body 131 and the process gas discharge space body 141 may be disposed at positions that face each other with the boat therebetween. The process gas injected into the process gas inflow space body 131 may pass through the gap between the substrates mounted on the boat by a pumping discharge pressure to flow into the process gas discharge space body 141, thereby being discharged to the outside. The process gas inflow space body 131 and the process gas discharge space body 141 may be buried in the sidewall of the upper chamber inner housing. Alternatively, the process gas inflow space body 131 and the process gas discharge space body 141 may be provided as separate mechanisms and then be coupled to each other in an inner surface of the sidewall.

For reference, FIG. 7 is a view of the process chamber when viewed from above, i.e., illustrates the process gas that flows along the other sidewall from one sidewall of the upper chamber inner housing according to an embodiment of the present invention. The process gas injected from the gas injection hole of the process gas inflow space body 130 may horizontally pass through the inner space of the upper chamber inner housing 110 to flow into the process gas discharge space body 140 disposed on the other sidewall that faces and opposite to the one sidewall. The process gas flow may be induced by a discharge pressure of the pump connected to the process gas discharge space body 140.

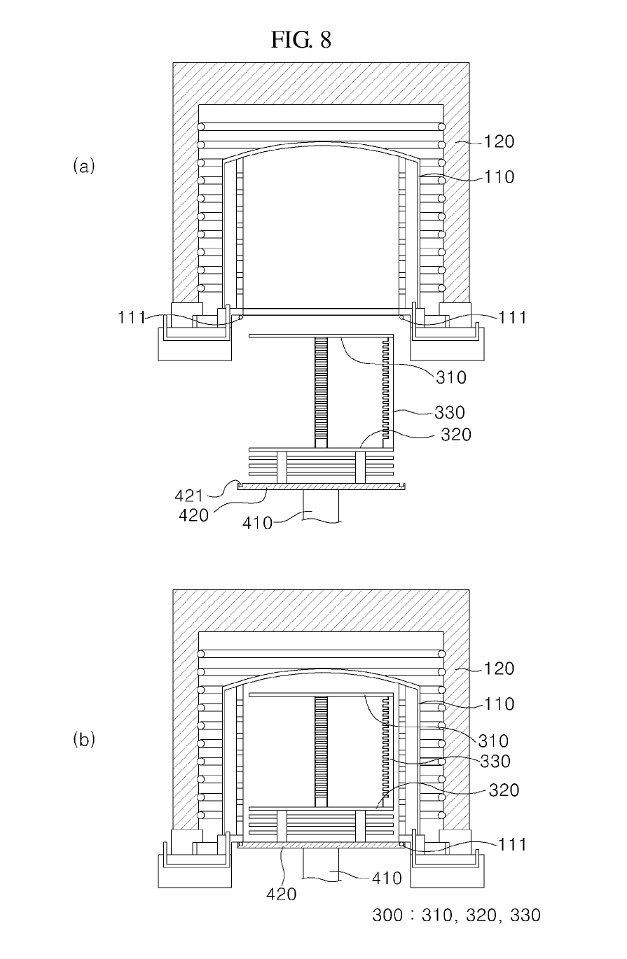

When the substrate is mounted on the boat 300 to ascend into the inner space of the upper chamber inner housing 110, the boat and the upper chamber housing may be sealed to maintain sealability with respect to the outside. To maintain the sealability (airtightness), the boat support 420 and the upper chamber inner housing 120 may be sealed by a sealing element coupling body such as an O-ring. For this, as illustrated in FIG. 8A, an O-ring groove 421 is defined in a top surface of an outer circumferential portion of the boat support 420. The top surface of the outer circumferential portion may be a surface that contacts a bottom surface of the upper chamber inner housing 110. An O-ring 111 may be defined on the bottom surface of the upper chamber inner housing 110 contacting the boat support 420, which faces the O-ring groove 421 of the boat support. Thus, when the boat 300 ascends and is accommodated into the upper chamber inner housing 110, the O-ring disposed on the bottom surface of the upper chamber inner housing may be inserted into the O-ring groove defined in the top surface of the boat support as illustrated in FIG. 8B to maintain the sealability.

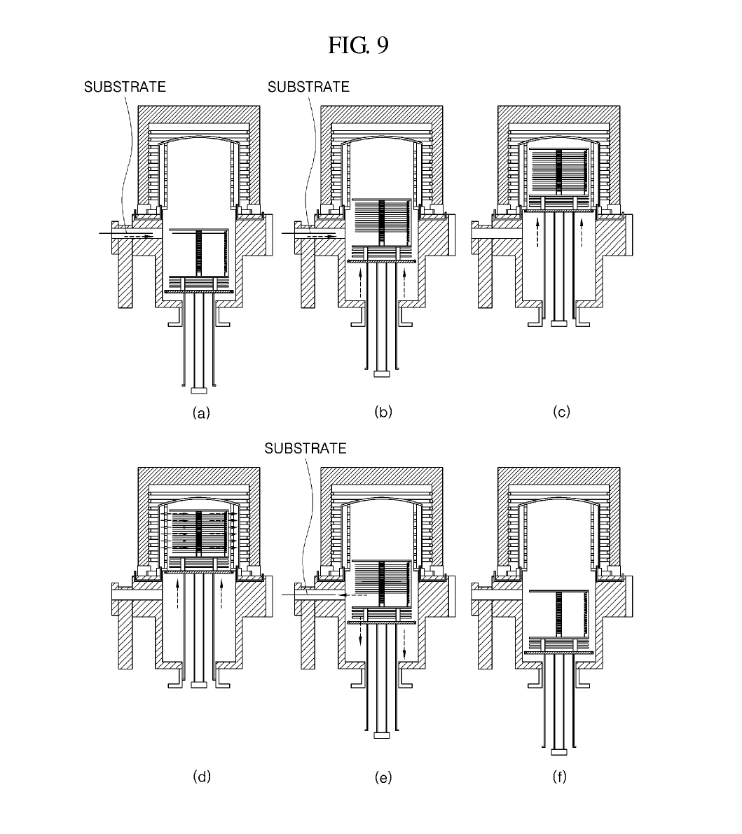

FIG. 9 is a view illustrating a process in which the substrate is loaded on the boat and is processed within a chamber housing, and then, is unloaded again from the boat according to an embodiment of the present invention.

When explaining a loading process, the substrate may be transferred to and seated into the substrate seat groove of the last stage of the boat through the substrate transfer gate as illustrated in FIG. 9A. When the substrate is seated, the boat may ascend so that the next substrate seat groove is disposed to correspond to the substrate transfer gate, and then the transferred substrate may be seated into the corresponding substrate seat groove. Thus, as illustrated in FIG. 9B, the boat ascends, and the substrate is seated into the substrate seat groove. When the substrate is seated as the boat ascends, as illustrated in FIG. 9C, the boat in which the substrate is seated into the substrate seat groove is accommodated into the upper chamber inner housing. Thereafter, as illustrated in FIG. 9D, the process gas flows out of the sidewall to contact the top surface of the substrate, thereby processing the top surface of the substrate. When the substrate processing process is completed, as illustrated in FIG. 9E, the substrate may be unloaded again from the chamber through the substrate transfer gate. When the substrate is completely unloaded, the boat is accommodated into the lower chamber housing as illustrated in FIG. 9F.

To improve the efficiency of the substrate processing, a heating device for heating the substrate may be provided in the process chamber. A heating unit for heating the substrates that are stacked to be spaced apart from each other in the boat within the second inner space of the upper chamber housing is necessary. The substrate heating device according to an embodiment of the present invention includes a first heater generating heat in a lower portion of the boat to heat the substrates and a second heater generating heat in a wall of the chamber housing (the upper chamber housing) to heat the substrates. One or all of the first and second heaters of the substrate heating devices may be provided.

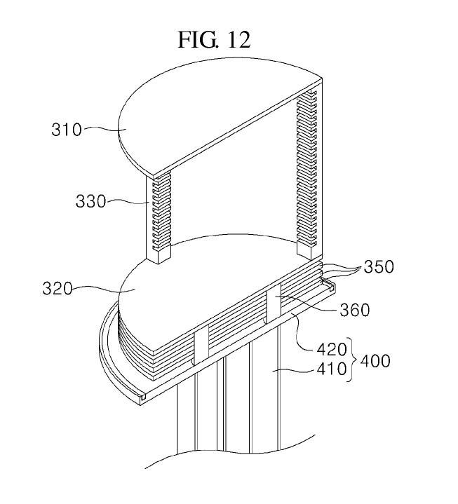

First, the first heater disposed in the boat will be described. When the first heater that is a heating unit is provided in the boat, the heating unit may be provided in the lower plate (or the upper plate) of the boat. The structure in which the first heater is disposed in the lower plate (or the upper plate) of the boat may be realized with two structures as followings. One structure may be a structure in which the heating unit is buried in the lower plate (or the upper plate) as illustrated in FIG. 11, and the other structure may be a structure in which a heating plate is disposed under the lower plate as illustrated in FIG. 12.

In case of the first structure in which the first heater such as a heat line is buried in the lower plate 320 and the upper plate 310 as illustrated in FIG. 11, heat energy may be directly supplied into the substrates that are stacked to be spaced apart from each other between the lower plate 320 and the upper plate 310.

In case of the second structure in which a heating plate as the heating unit is separately provided as illustrated in FIG. 12, heat energy may be supplied into the substrates by heating the lower plate. In case of the structure in which the heating plate is provided, the first heater includes a support shaft connecting the lower plate 320 and the boat support 420 to each other in a state where the lower plate 320 and the boat support 420 are spaced apart from each other and a heating plate 350 fixed by the support shaft and horizontally disposed in a space defined between the lower plate 320 and the boat support 420. The heating plate 350 may be provided in plurality, and then, the plurality of heating plates 350 may be horizontally stacked to generate heat energy. The heating plate 350 may be provided as a conductor that generates heat in the plate in itself, or the heat line may be buried in the heating plate to generate heat energy.

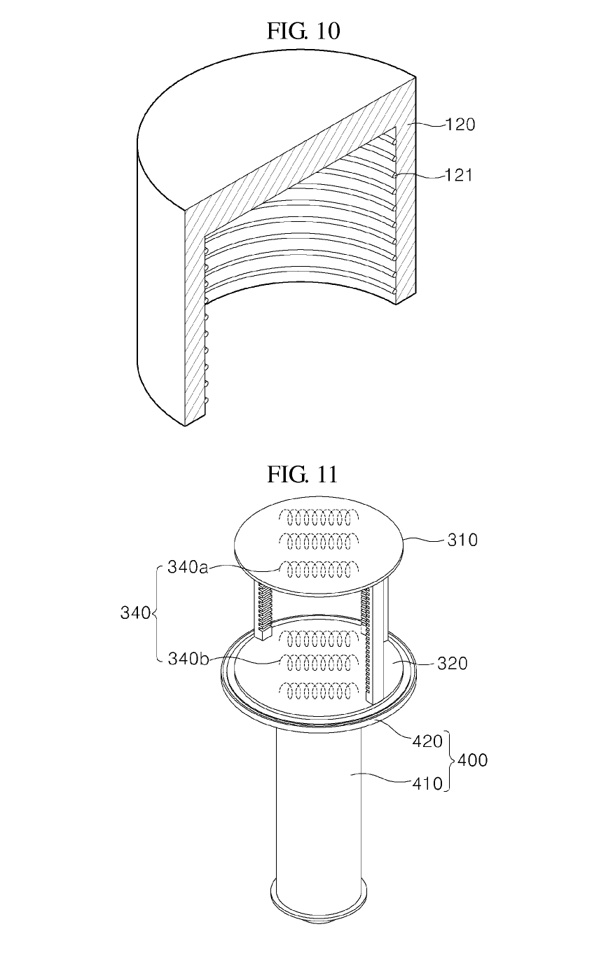

In case of the second heater that is the heating unit is provided in the chamber housing, the second heater may be disposed in the chamber housing. That is, the second heater may be disposed in at least one of the upper chamber outer housing and the upper chamber inner housing. The second heater may be provided in at least one of an inner wall of the upper chamber outer housing and an outer wall of the upper chamber inner housing. The second heater may be realized as various heating units such as the heat line. FIG. 10 is a view illustrating a state in which the heat line that is the second heater is provided in the inner wall of the upper chamber inner housing. A heat line that is the second heater according to an embodiment may be disposed in a zigzag shape in the inner wall of the upper chamber outer housing 120. Alternatively, the heat line may be disposed in a zigzag in the outer wall of the upper chamber inner housing. Alternatively, the heat line 121 may protrude from the inner wall of the upper chamber outer housing (or the inner wall of the upper chamber inner housing). Alternatively, the heat line 121 may be buried in the inner wall of the upper chamber outer housing (or the inner wall of the upper chamber inner housing). Also, the heat line 121 may be adjusted in temperature so that areas of the wall of the chamber housing have temperatures different from each other. Since the areas of the wall are differently adjusted in temperature as necessary, temperatures in the upper and lower sides within the process chamber may be equally maintained by adjusting the temperatures of the areas. For example, when the process gas discharge space body has a temperature lower than that of the other portion, the heat line may be controlled in temperature so that the wall of the process gas discharge space body further increases in temperature. Also, four heating areas of the chamber housing may be provided. In some cases, the number of heating areas may increase or decrease.

The process chamber and the substrate processing device according to an embodiment of the present invention may be applied to device for processing various processes such as such as the chemical vapor deposition (CVD) and the atomic layer deposition (ALD). Also, according to an embodiment of the present invention, the process chamber for injecting a gas from the sidewall thereof to discharge the gas through the other side may be used to manufacture semiconductors such as LED devices and memory devices. However, the present invention is not limited thereto. For example, the process chamber may be applied to manufacture flat panel substrates such as LCDs and SOLARs.

Also, in the process chamber according to the foregoing embodiment of the present invention, the lower chamber housing may function as the substrate loading chamber, and the upper chamber housing may function as the process chamber into which the process gas is injected. However, the present invention is not limited thereto. For example, it is obvious that the prevent invention may also be applied to a structure in which the lower chamber housing functions as the process chamber for injecting the process gas, and the upper chamber housing functions as the substrate loading chamber.

Although the present invention has been described with reference to the accompanying drawings and foregoing embodiments, the present invention is not limited thereto and also is limited to the appended claims. Thus, it is obvious to those skilled in the art that the various changes and modifications can be made in the technical spirit of the present invention.

1. A substrate heating device comprising a boat in which a plurality of substrates are stacked to be spaced apart from each other and a chamber housing in which the boat is disposed in an inner space thereof to inject a process gas between substrates that are stacked to be spaced apart from each other in the boat through an injection hole defined in an inner sidewall thereof, the substrate heating device comprising:
a first heater configured to generate heat in a lower portion of the boat to heat the substrates.

2. The substrate heating device chamber of claim 1, wherein the boat comprises:
an upper plate;
a lower plate;
a plurality of support bars connecting the upper plate to the lower plate; and
a plurality of substrate seat grooves defined in sidewalls of the support bars.

3. The substrate heating device chamber of claim 2, wherein the first heater is disposed on a top surface of the lower plate or a bottom surface of the upper plate.

4. The substrate heating device chamber of claim 2, wherein the first heater is buried in the lower plate or the upper plate.

5. The substrate heating device chamber of claim 2, wherein the boat elevation unit comprises:
a boat support configured to support the lower plate; and
an elevation rotation driving shaft passing through a bottom surface of the lower chamber housing to elevate the boat support.

6. The substrate heating device chamber of claim 5, wherein the first heater comprises:
a support shaft connecting the lower plate to the boat support in a state where the lower plate and the boat support are spaced apart from each other; and
a heating plate fixed to the support shaft, the heating plate being horizontally disposed in a space defined between the lower plate and the boat support.

7. The substrate heating device chamber of claim 1, further comprising a second heater configured to generate heat in a wall of the chamber housing to heat the substrates.

8. The substrate heating device chamber of claim 7, wherein the second heater comprises a heat line.

9. The substrate heating device chamber of claim 8, wherein the heat line protrudes from an inner sidewall of the chamber housing.

10. The substrate heating device chamber of claim 8, wherein the heat line is buried in the wall of the chamber housing.

11. The substrate heating device chamber of any one of claims claim 9, wherein the heat line heats areas of the wall of the chamber housing at temperatures different from each other.

12. A process chamber comprising:
a boat in which a plurality of substrates are stacked to be spaced apart from each other;
a chamber housing configured to lift the boat, thereby allowing the boat to be disposed in an inner space thereof, the chamber housing being configured to horizontally inject a process gas from a sidewall thereof, thereby allowing the process gas to flow between the substrates stacked to be apart from each other and discharge the process gas to the outside;
a boat elevation unit configured to elevate the boat into the chamber housing;
a substrate transfer gate passing through one sidewall of the chamber housing; and
a heating unit disposed in the boat within the inner space of the chamber housing to heat the substrates that are stacked to be spaced apart from each other.

13. The process chamber of claim 12, wherein the chamber housing comprises:
a lower chamber housing having a first inner space that is an inner space thereof;
an upper chamber housing disposed above the lower chamber housing and having a second inner space that is an inner space thereof, the upper chamber housing being configured to horizontally inject the process gas from one side inner wall thereof, thereby allowing the process gas to flow between the substrates stacked to be spaced apart from each other and discharge the process gas to the outside.

14. The process chamber of claim 13, wherein the heating unit comprises a first heater that generates heat in a lower portion of the boat to heat the substrates.

15. The process chamber of claim 14, wherein the boat comprises:
an upper plate;
a lower plate;
a plurality of support bars connecting the upper plate to the lower plate; and
a plurality of substrate seat grooves defined in sidewalls of the support bars.

16. The process chamber of claim 15, wherein the first heater is disposed on a top surface of the lower plate or a bottom surface of the upper plate.

17. The process chamber of claim 15, wherein the first heater is buried in the lower plate or the upper plate.

18. The process chamber of claim 15, wherein the boat elevation unit comprises:
a boat support configured to support the lower plate; and
an elevation rotation driving shaft passing through a bottom surface of the lower chamber housing to elevate the boat support.

19. The process chamber of claim 18, wherein the first heater comprises:
a support shaft connecting the lower plate to the boat support in a state where the lower plate and the boat support are spaced apart from each other; and
a heating plate fixed to the support shaft, the heating plate being horizontally disposed in a space defined between the lower plate and the boat support.

20. The process chamber of claim 13, further comprising a second heater configured to generate heat in a wall of the chamber housing to heat the substrates.
